(19) United States
(12) Patent Application Publication
(10) Pub. No.: US 2020/0001640 A1
(43) Pub. Date: Jan. 2, 2020

(54) METHODS AND APPARATUS FOR PROVIDING IMPROVED VISUAL FEATURES ON A SUBSTRATE

(71) Applicant: CORNING INCORPORATED, CORNING, NY (US)

(72) Inventors: Matthew Wade Fenton, Elmira, NY (US); Timothy James Kiczenski, Corning, NY (US)

(21) Appl. No.: 16/457,049

(22) Filed: Jun. 28, 2019

Related U.S. Application Data
(60) Provisional application No. 62/691,141, filed on Jun. 28, 2018.

(51) Int. Cl. B41M 5/00; G02B 5/08; H05K 5/00; H05K 5/03; H05K 5/02

(52) U.S. Cl. CPC B41M 5/0011; G02B 5/0808; H05K 5/0243; H05K 5/03; H05K 5/0017

(57) ABSTRACT

Methods and apparatus provide for improved visual features on a visible element of an article, such as a consumer electronic device.

### CROSS-REFERENCE TO RELATED APPLICATION

This application claims the benefit of priority under 35 U.S.C. § 119 of U.S. Provisional Application Ser. No. 62/691141 filed on Jun. 28, 2018, the content of which is relied upon and incorporated herein by reference in its entirety.

### BACKGROUND

The present disclosure relates to methods and apparatus for providing improved visual features on a substrate, such as on a substrate used in a commercial article.

As the sophistication of consumers continues to evolve and increase, the importance of aesthetic features, especially the integration of form and function, also increases. This is evident in the field of consumer electronics, such as in the design of mobile electronic devices (such as, mobile phones, smartphones, watches, tablets, phablets, notebook computers, laptops, other types of computers, navigation systems, and the like). There have been many instances in which a consumer electronic device that exhibits some enhanced aesthetic feature over competing devices will enjoy significantly higher acceptance in the marketplace, even when the devices exhibit relatively comparable functional characteristics.

For example, there have been efforts in the marketplace to add a visual element, such as an image or color feature, to some surface(s) of an electronic device, such as to the back side of a mobile phone (and/or any of the other devices mentioned herein). A previously employed approach to achieving the visual element on an electronic device has been to apply ink (e.g., via ink jet printing) onto a substrate of the device. While consumers have come to accept, and even desire, such a visual element, a consistent issue with previous efforts is the relatively grainy appearance of the visual element to a viewer.

Accordingly, there are needs in the art for new methods and apparatus for providing visual features on a substrate.

### SUMMARY

The present disclosure relates to methods and apparatus for providing one or more improved visual features on a visible element (e.g., a substrate) of an article.

In accordance with one or more embodiments, an article may include some form of a housing in which functional elements of the article are disposed. For example, the housings of many smartphone devices include a touchscreen on a front side of the article and a substrate on the back side of the article. In rather basic configurations, the substrate on the back side of the article may be opaque, such as black or white. More interesting visual elements may include color, color and/or patterns, designs, images, etc.

In robust applications, such visual elements (especially printed elements, such as ink jet printed visual elements) may be disposed on an inner surface (e.g., an inwardly facing surface of the substrate or, in other words, a surface facing the interior of the housing) of a transparent (or partially transparent) substrate, such as a glass substrate, a glass-ceramic substrate, or a polymer substrate. Thus, the visual element may be seen by the user through the substrate but the visual element is protected from wear or damage by way of being disposed on the inwardly facing surface of the substrate.

The respective embodiments, individual features thereof, and/or sets of features thereof, disclosed and discussed herein are exemplary and may be provided alone or in any combination with any one or more other disclosed features without departing from the scope of the disclosure.

Other aspects, features, and/or advantages will be apparent to one skilled in the art from the description herein taken in conjunction with the accompanying drawings.

### DESCRIPTION OF THE DRAWINGS

For the purposes of illustration, there are forms shown in the drawings, it being understood, however, that the embodiments disclosed and described herein are not limited to the precise arrangements and instrumentalities shown.

FIG. 1 includes a top view and a perspective view of a substrate having one or more image features therewith;

FIGS. 2-3 are schematic diagrams of the substrate of FIG. 1 as it moves through a process for disposing one or of the image features thereon;

FIGS. 4-5 are schematic diagrams of the substrate exhibiting certain light altering features in connection with the one or more image features;

FIG. 6 includes a perspective view of a substrate and supplemental substrate arrangement having one or more image features therewith;

FIG. 7 is a plan view of an exemplary electronic device incorporating any number of the improved image features disclosed herein; and

FIG. 8 is a perspective view of the exemplary electronic device of FIG. 7.

### DETAILED DESCRIPTION OF THE EMBODIMENTS

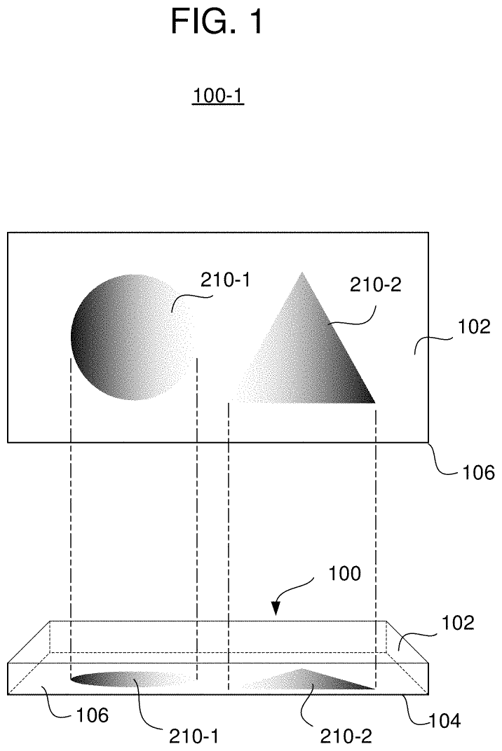

With reference to the drawings, wherein like numerals indicate like elements, there is shown in FIG. 1 an apparatus 100-1, primarily comprising a substrate 100, in accordance with one or more embodiments of this disclosure.

As mentioned above, among the applications of the apparatus 100-1 is to provide a visible element of an article, such as an electronic device, an architectural article, a transportation article, an appliance article, etc. In some embodiments, the substrate 100 of the apparatus 100-1 may also be a structural element of the article, such as forming part of a housing thereof. By way of example, the substrate 100 may be formed from glass material, glass ceramic material, strengthened glass material, strengthened glass-ceramic material, and polymer material. When the substrate 100 is formed from strengthened glass (or glass-ceramic), such may be thermally strengthened or chemically-strengthened, for example via an ion-exchange process.

The substrate 100 includes a first major surface 102, a second major surface 104 opposite the first major surface 102, and at least one edge surface 106 extending between the first and second major surfaces 102, 104. By way of example, an article (e.g., a mobile electronics device) that comprises the apparatus 100-1 may include a housing within which components of the article are disposed, and wherein the first major surface 102 of the substrate 100 forms an outer surface of the housing. Thus, the user of the article may both see and touch the first major surface 102 of the substrate 100 when handling the housing of the article.

As previously mentioned, desirable characteristic(s) of the housing of the article include providing improved visual features via the first major surface 102 of the substrate 100. In this regard, the substrate 100 includes at least one visual element 210-1, 210-2 disposed on the second major surface 104 of the substrate 100 such that the at least one visual element may be viewed through the first major surface 102 thereof. In one or more embodiments, the at least one visual element 210-1, 210-2 is disposed on the second major surface 104 of the substrate 100 via an ink application process, such as an ink-jet printing process.

The at least one visual element 210-1, 210-2 may include one or more visual portions arranged into at least one of: (i) one or more areas of color, (ii) one or more lines, (iii) one or more patterns, (iv) one or more designs, (v) one or more images, and/or (vi) one or more combinations thereof. By way of example, the at least one visual element may include a first visual element 210-1 (e.g., a circle formed via color, lines, patterns, shading, design, etc.), and a second visual element 210-2 (e.g., a triangle formed via color, lines, patterns, shading, design, etc.). Those skilled in the art will appreciate that the particular artistic elements comprised within the at least one visual element 210-1, 210-2 are seemingly infinite, and the illustrated examples are not limiting.

As will be discussed in greater detail later herein, the at least one visual element 210-1, 210-2 may be printed on the second major surface 104 of the substrate 100, serving as an inner surface (e.g., an inwardly facing surface of the substrate 100 or, in other words, a surface facing an interior of the housing of the article). Thus, the at least one visual element 210-1, 210-2 may be seen by the user through the substrate 100 but the at least one visual element 210-1, 210-2 is protected from wear or damage by way of being disposed on the inwardly facing surface (i.e., the second major surface) 104 of the substrate 100.

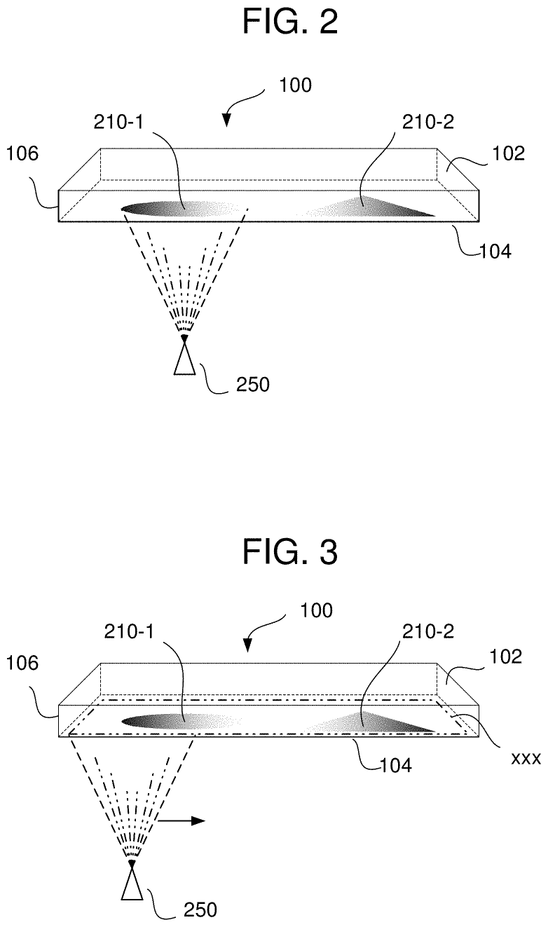

A process for achieving the application of the at least one visual element 210-1, 210-2 directly to the substrate 100 will be discussed with reference to FIGS. 2-3, which contain schematic drawings of a substrate 100 as it moves through the process. As shown in FIG. 2, the at least one visual element 210-1, 210-2 is achieved by applying at least one layer of imaging material directly to the second major surface 104 of the substrate 100. Such application may involve ink printing, ink spraying, coating techniques, photolithography, etc. via suitable equipment 250 known to skilled artisans. It is noted that ink jet printing (i.e., employing ink as an imaging material in an ink jet process) is considered to exhibit rather substantial graininess as compared to other techniques (such as compared to pad printing, screen printing, deco films, etc.) Notably, the at least one layer of imaging material may include multiple layers of such imaging material built up one over another.

Irrespective of the particular technique employed, the imaging material applied directly to the second major surface 104 of the substrate 100 achieves the aforementioned one or more visual elements 210-1, 210-2 arranged into at least one of: (i) one or more areas of color, (ii) one or more lines, (iii) one or more patterns, (iv) one or more designs, (v) one or more images, and/or (vi) one or more combinations thereof.

With reference to FIG. 3, a process for enhancing the visibility of the at least one visual element 210-1, 210-2 through the first major surface 102 of the substrate 100 is carried out. For example, a bright (and preferably neutral) reflective layer 280 (also referred to herein as a backing layer), such as a light pigment (e.g., white), is applied over (e.g., behind) the at least one visual element 210-1, 210-2 on the second major surface 104 by way of printing, coating, spraying, etc. using suitable equipment 250 known to skilled artisans. The reflective layer 280 may be formed from a light pigment (e.g., white), a shiny dark pigment (e.g., black), and/or a metallic coating, etc.

As mentioned above, when certain techniques are used to apply the at least one visual element 210-1, 210-2 on the surface (in this embodiment, the second major surface 104) of the substrate 100, such as via ink jet printing, an undesirable level of graininess may be exhibited to the viewer, which look artificial and/or cheap, particularly when printing abstract images (e.g., gradients or patterns instead of photographs).

In the context of this disclosure, graininess exhibits an undesirable visual effect on the viewer by aperiodic fluctuations of density at a spatial frequency greater than 0.4 cycles per millimeter in all directions, which is defined by ISO/IEC 13660 (2001(E)), the entire disclosure of which is hereby incorporated by reference. Such graininess may be expressed mathematically (and therefore measured) as follows: graininess across a region of interest (ROI) is √((Σi(σi)̂2)/n), where σ1 is a standard deviation of optical density measurements within tile i, and n is a total number of tiles in the ROI. In the context of this disclosure, optical density is a quantity describing a magnitude of an image. By way of example, optical density is expressed as log 10 (1/R), where R is a reflectance factor, measured according with 0/45-degree geometry, Illuminant A, and ISO visual density calibration, see ISO/IEC 13660 (2001(E)). Notably, graininess is not the same as pixelation, which is characterized by other undesirable features due to forming an image via a bitmap of individual pixels, and which may be characterized by low resolution visible to a viewer.

It has been discovered that the aforementioned graininess of the at least one visual element 210-1, 210-2, (as seen by the viewer) may be substantially reduced by an opacity of the at least partially transparent material of the substrate 100 as light reflects off of the backing layer 280 (or other discontinuity), through the at least one layer of the imaging material (i.e., the at least one visual element 210-1, 210-2), and through the substrate 100 to the viewer. More particularly, the graininess of the at least one visual element 210-1, 210-2, may be effectively reduced when the substrate is formed from an at least partially transparent material having an opacity of a minimum threshold. Based on extensive experimentation, the minimum opacity has been determined to be about 13.0% or more, 13.5% or more, 14.0% or more, 14.5% or more, 15.0% or more, 15.5% or more, 16.0% or more, 16.5% or more, 17.0% or more, 17.5% or more, or 18.0% or more. These percentages are based on the fact that an opacity of about 12.83% is characteristic of clear glass, an opacity of about 12.95% is characteristic of glass having an anti-glare haze (e.g., about 32% haze), and an opacity of about 18.96% is characteristic of relatively foggy glass (e.g., about 99% haze). In some embodiments, the partially transparent material can have an opacity of 13.0% or more, 13.5% or more, 14.0% or more, 14.5% or more, 15.0% or more, 15.5% or more, 16.0% or more, 16.5% or more, 17.0% or more, 17.5% or more, 18.0% or more, 18.5% or more, 19.0% or more, 19.5% or more, 20.0% or more, 25.0% or more, 30.0% or more, 35.0% or more, 40.0% or more, 45.0% or more, 50.0% or more, 55.0% or more, 60.0% or more, 65.0% or more, 70.0% or more, 75.0% or more, 80.0% or more, 85.0% or more, 90.0% or more, and any ranges and subranges therebetween.

In the context of this disclosure, opacity jis considered as an indication of a scattering effect on light as it passes through the substrate 100. Due to spacing between respective locations of such scattering and the imaging material (e.g., ink) located on the second major surface 104 of the substrate 100, the noted positive affect on the graininess is achieved. Another way of describing opacity is in terms of setting translucency of a material to a level of opacity. As used herein, opacity is expressed as the opacity contrast ratio (a percentage). The opacity contrast ratio of a substrate 100 is measured using a model color i7 spectrophotometer manufactured and sold by X-Rite Incorporated, Grand Rapids, Mich. The specific opacity contrast ratios discussed herein were determined using and/or as a result of measurements taken using the aforementioned i7 spectrophotometer under certain conditions and settings. These conditions and settings include using the specific white/black ceramic measurement tiles provided with the spectrophotometer, employing a D-65 illuminant during measurements (which simulates daylight conditions), and taking reflectance measurements with the SCI (specular included) mode with the MAV aperture setting.

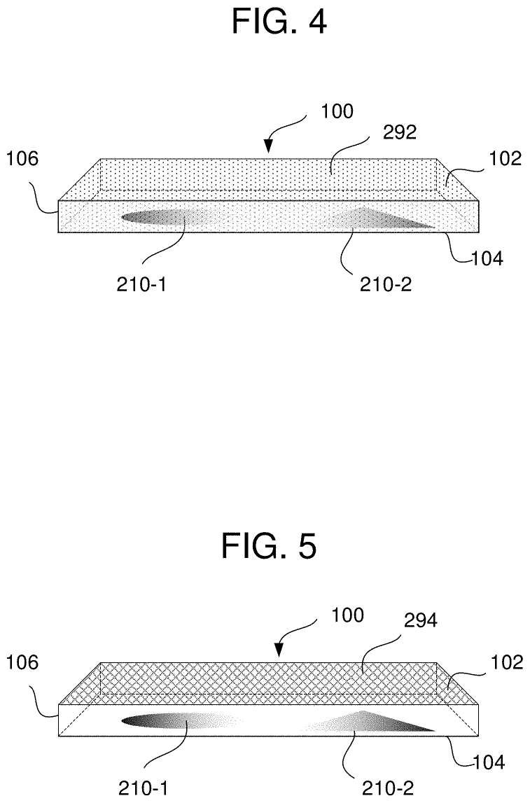

As shown in FIG. 4, the opacity of the at least partially transparent material of the substrate 100 may be achieved via one or more elements 292 within the substrate 100 itself, such as pigment, inclusions, etc. In some embodiments, when substrate 100 is a glass-ceramic, the opacity/partial transparency may be achieved through the crystalline phases present in the glass-ceramic and/or the heat treatments used to transform a glass into a glass-ceramic.

Alternatively and/or additionally, as shown in FIG. 5, the opacity of the at least partially transparent material of the substrate 100 may be achieved via a surface element 294 on one or more of the first and second major surfaces 102, 104 of the substrate 100. For example, surface element 294 may be one or more of a haze, a roughness, a texture, one or more films, one or more layers of pigment, etc.

It has been discovered that when the substrate 100 is formed from an at least partially transparent material having an opacity of about 20% to 30%, the graininess of an image (formed via the at least one layer of the imaging material, i.e., the at least one visual element 210-1, 210-2) is reduced by about a factor of two. In other words, the improvement (i.e., the reduction in the apparent graininess as seen by the viewer) is in direct response to the opacity of the substrate 100.

It has also been discovered that when the substrate 100 is formed from an at least partially transparent material having an opacity of about 40% to 60%, the graininess of an image (formed via the at least one layer of the imaging material, i.e., the at least one visual element 210-1, 210-2) is reduced by about a factor of four. Again, the improvement (i.e., the reduction in the apparent graininess as seen by the viewer) is in direct response to the opacity of the substrate 100.

It has been discovered that increasing the opacity of the substrate 100 (in order to reduce the apparent graininess of the image) may also reduce the apparent brilliance of the image itself (i.e., the at least one visual element 210-1, 210-2). Accordingly, a saturation of the image may be increased as a function of increasing the opacity of the at least partially transparent material of the substrate 100. By way of example, increasing the saturation of the image may be achieved by increasing the total number of layers forming the at least one layer of the imaging material (i.e., the number of layers forming the at least one visual element 210-1, 210-2). Another way of considering the increase in saturation is to increase the optical density of the imaging material. Preferably, the saturation of the image is increased in substantially equal magnitudes as the increasing of the opacity of the at least partially transparent material of the substrate 100 in order to achieve balanced results.

Experiments were conducted in order to demonstrate the noted effect of reducing graininess of an imaging material (deposited via an ink jet process) on a surface of a glass substrate by increasing opacity. In particular, a number of alkali-aluminosilicate glass substrates where prepared by ink jet printing a color gradient on one side thereof, which transitioned from magenta to cyan. Thus, the color gradient transitioned from a first zone (pure magenta), to a second zone (a mix of magenta and cyan), to a third zone (pure cyan). Variations in the optical density (saturation) of the color gradient and variations in the opacity contrast ratio (again, referred to as “opacity” herein) of the substrates were made. The resulting graininess levels were measured using the i7 spectrophotometer using the conditions and settings discussed above.

A first group of the substrates were prepared by applying three layers of the imaging material (i.e., ink) to one side of the substrates, yielding a first optical density (saturation) of the magenta to cyan color gradient. Within this first group of substrates, some had an opacity of about 12.83%, which is substantially clear glass. Others of the substrates had a higher opacity of about 24.46%, which is a somewhat translucent glass. Still others of the substrates had an even higher opacity of about 78.76%, which is a relatively heavy translucent glass. The variations in opacity were achieved via variations in heat treatment of the substrates, which had a direct effect on opacity. Measurements of the graininess of the imaging material among the respective substrates of 12.83%, 24.46%, and 78.76% opacity, respectively, yielded: (i) 9.3, 6.6, 3.0 (in the first zone, magenta); (ii) 9.2, 5.0, 2.3 (in the second zone, mix of magenta and cyan); and (iii) 7.5, 3.3, 1.1 (in the third zone, cyan). Thus, while the graininess of imaging material in the first zone (magenta) was generally higher than the graininess of imaging material in the second and third zones, the graininess in all zones improved (reduced) significantly as a function of increasing the opacities of the substrates, such as from 12.83% through 78.76%.

A second group of the substrates were prepared by applying six layers of the imaging material (i.e., ink) to one side of the substrates, yielding a second optical density (saturation) of the magenta to cyan color gradient. The second optical density is believed to be about double that of the first optical density of the first group of the substrates. Similarly to the first group of substrates, within this second group of substrates, some had an opacity of about 12.83%, others had a higher opacity of about 24.46%, and still others had an even higher opacity of about 78.76%. Measurements of the graininess of the imaging material among the respective substrates yielded: (i) 7.9, 4.4, 1.5 (in the first zone, magenta); (ii) 9.3, 2.0, 0.7 (in the second zone, mix of magenta and cyan); and (iii) 11.1, 2.0, 0.5 (in the third zone, cyan). The increase in optical density of the imaging material is believed to improve the visibility of the imaging material in the presence of increased opacity of the substrates. Again, the graininess in all zones improved (reduced) significantly as a function of increasing the opacities of the substrates.

A third group of the substrates were prepared by again applying three layers of the imaging material (i.e., ink) to one side of the substrates, yielding the aforementioned first optical density (saturation) of the magenta to cyan color gradient. Similarly to the first and second groups of substrates, within this third group of substrates, some had an opacity of about 12.83%, others had a higher opacity of about 24.46%, and still others had an even higher opacity of about 78.76%. Instead of measuring graininess, however, a related quantity, called mottle, was measured. Mottle is defined as a standard deviation of an average reflectance values of the tiles defined in ISO/IEC 13660 (2001(E)). In other words, mottle provides an indication of how much variation in density exists from one tile to another. Measurements of the mottle of the imaging material among the respective substrates yielded: (i) 1.6, 1.2, 0.9 (in the first zone, magenta); (ii) 1.7, 1.1, 0.9 (in the second zone, mix of magenta and cyan); and (iii) 1.4, 1.1, 0.8 (in the third zone, cyan). The mottle in all zones improved (reduced) significantly as a function of increasing the opacities of the substrates, such as from 12.83% through 78.76%.

A fourth group of the substrates were prepared by again applying six layers of the imaging material (i.e., ink) to one side of the substrates, yielding the aforementioned second optical density (saturation) of the magenta to cyan color gradient. Also within this fourth group of substrates, some had an opacity of about 12.83%, others had a higher opacity of about 24.46%, and still others had an even higher opacity of about 78.76%. Measurements of the mottle of the imaging material (i.e., of higher saturation as compared with the third group of substrates) among the respective substrates yielded: (i) 1.4, 1.1, 0.8 (in the first zone, magenta); (ii) 1.7, 0.9, 0.8 (in the second zone, mix of magenta and cyan); and (iii) 2.0, 1.0, 0.8 (in the third zone, cyan). Again, the mottle in all zones improved (reduced) significantly as a function of increasing the opacities of the substrates.

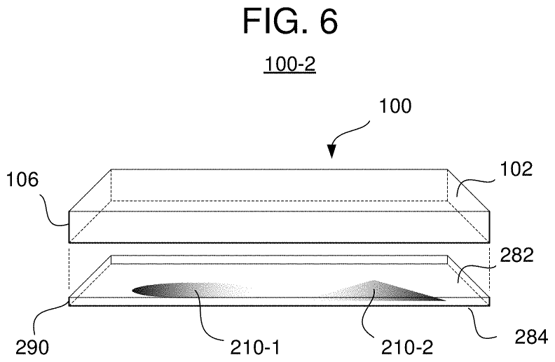

With reference to FIG. 6, an alternative structure 100-2 is disclosed with regards to the application of the at least one visual element 210-1, 210-2 and a substrate 100. In particular, instead of (and/or in addition to) direct application of the at least one visual element 210-1, 210-2 onto the second major surface 104 of the substrate 100, the at least one visual element 210-1, 210-2 may be applied to a secondary substrate 290, such as to one (or both) of a first major surface 282 and a second major surface 284 thereof. Such application may be achieved using the aforementioned technique(s) with respect to FIGS. 2-3. The secondary substrate 290 is then combined with the substrate 100 to form the structure 100-2. In this regard, the at least one visual element 210-1, 210-2 is indirectly applied to the second major surface 104 of the substrate 100.

The embodiments disclosed herein may be incorporated into a product, such as an article with a display (or display articles, such as consumer electronics, including mobile phones, watches tablets, computers, navigation systems, and the like), architectural articles, transportation articles (e.g., automotive, trains, aircraft, sea craft, etc.), appliance articles, or any article that may benefit from some transparency, visual enhancement, scratch-resistance, abrasion resistance or a combination thereof.

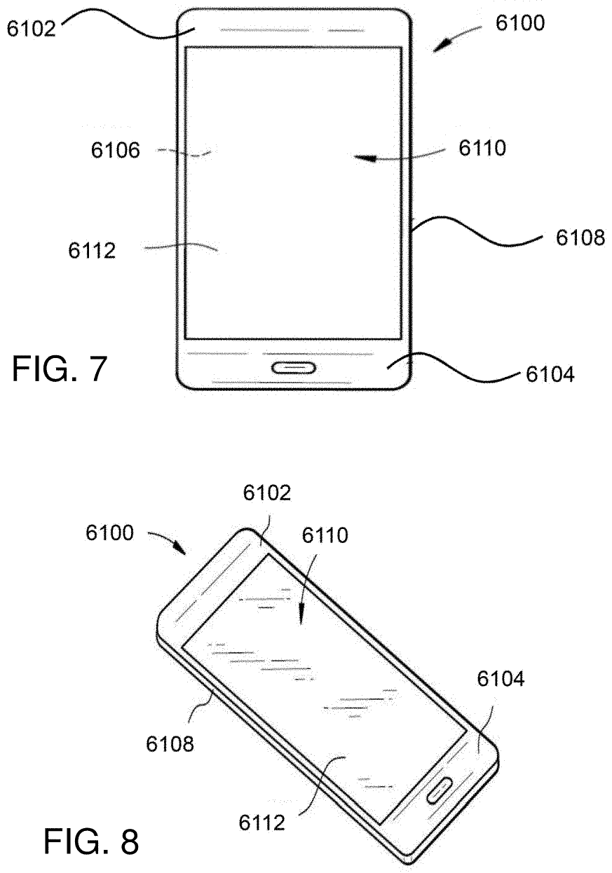

An exemplary article incorporating any number of the image improving features disclosed herein is shown in FIGS. 7 and 8. Specifically, FIGS. 7 and 8 show a consumer electronic device 6100 including a housing 6102 having front 6104, back 6106, and side surfaces 6108; electrical components (not shown) that are at least partially inside or entirely within the housing and including at least a controller, a memory, and a display 6110 at or adjacent to the front surface of the housing; and a cover substrate 6112 at or over the front surface of the housing such that the cover substrate 6112 is over the display.

In one or more embodiments, the cover substrate 6112 may include any of the image improving features disclosed herein.

In one or more embodiments, at least one of a portion of the housing 6102 and/or the cover substrate 6112 comprises the image improving features disclosed herein.

In an aspect 1, a method comprises: applying at least one layer of an imaging material to form an image into direct or indirect contact with one of a first major surface and a second major surface of a substrate, where the second major surface is opposite the first major surface, and the substrate includes at least one edge surface extending between the first and second major surfaces, wherein the substrate is formed from an at least partially transparent material having an opacity of 13.5% or more.

An aspect 2 according to aspect 1, wherein the at least partially transparent material has an opacity of at least one of: 14.0%, 14.5%, 15.0%, 15.5%, or 16.0%

An aspect 3 according to aspect 1 or 2, wherein one of the imaging material is applied directly onto the one of the first major surface and the second major surface of the substrate; and the imaging material is applied onto a surface of a secondary substrate that is positioned relative to the one of the first major surface and the second major surface of the substrate.

An aspect 4 according to any preceding aspect, further comprising applying at least one backing layer of a reflective material over the at least one layer of the imaging material.

An aspect 5 according to aspect 4, wherein: the imaging material includes one or more inks; the applying of the imaging material includes an ink printing technique; and the image exhibits a graininess, an appearance of which is substantially reduced by the opacity of the at least partially transparent material of the substrate as light reflects off of the backing layer, through the at least one layer of the imaging material, and through the substrate to a viewer.

An aspect 6 according to aspect 5, wherein the graininess of the image is a function of a degree of variation in density of the ink of the imaging material within a given area.

An aspect 7 according to aspect 6, wherein: the substrate is formed from an at least partially transparent material having an opacity of between about 20% to 30%; and the graininess of the image is reduced by about a factor of two in response to the opacity of at least about 20% to 30%.

An aspect 8 according to aspect 6, wherein: the substrate is formed from an at least partially transparent material having an opacity of between about 40% to 60%; and the graininess of the image is reduced by about a factor of four in response to the opacity of at least about 40% to 60%.

An aspect 9 according to any preceding aspect, further comprising increasing a saturation of the image as a function of increasing the opacity of the at least partially transparent material of the substrate.

An aspect 10 according to aspect 9, further comprising increasing the saturation of the image by increasing a total number of layers forming the at least one layer of the imaging material.

An aspect 11 according to aspect 9, further comprising increasing the saturation of the image in substantially equal magnitudes as the increasing of the opacity of the at least partially transparent material of the substrate.

An aspect 12 according to any preceding aspect, further comprising establishing the opacity of the at least partially transparent material of the substrate by at least one of hazing the substrate and texturing the substrate.

An aspect 13 according to any preceding aspect, wherein the substrate comprises one of glass material, glass ceramic material, strengthened glass material, strengthened glass-ceramic material, and polymer material.

In an aspect 14, an apparatus comprises: a substrate having a first major surface, a second major surface opposite the first major surface, and at least one edge surface extending between the first and second major surfaces, where the first substrate is formed from an at least partially transparent material having an opacity of 13.5% or more; and at least one layer of an imaging material in direct or indirect contact with one of the first major surface and the second major surface of the substrate to form an image.

An aspect 15 according to aspect 14, wherein the at least partially transparent material has an opacity of at least one of: 14.0%, 14.5%, 15.0%, 15.5%, or 16.0%

An aspect 16 according to aspect 14 or 15, wherein one of: the imaging material is in direct contact with the one of the first major surface and the second major surface of the substrate; and the imaging material is on a surface of a secondary substrate that is positioned relative to the one of the first major surface and the second major surface of the substrate.

An aspect 17 according to any one of aspects 14-16, further comprising at least one backing layer of a reflective material applied over the at least one layer of the imaging material.

An aspect 18 according to aspect 17, wherein: the imaging material includes one or more inks; the imaging material includes a printed ink; and the image exhibits a graininess, an appearance of which is substantially reduced by the opacity of the at least partially transparent material of the substrate as light reflects off of the backing layer, through the at least one layer of the imaging material, and through the substrate to a viewer.

An aspect 19 according to aspect 18, wherein the graininess of the image is a function of a degree of variation in contrast of the ink of the imaging material within a given area.

An aspect 20 according to aspect 19, wherein the substrate is formed from an at least partially transparent material having an opacity of between about 20% to 30%; and the graininess of the image is reduced by about a factor of two in response to the opacity of at least about 20% to 30%.

An aspect 21 according to aspect 19, wherein:

the substrate is formed from an at least partially transparent material having an opacity of between about 40% to 60%; and the graininess of the image is reduced by about a factor of four in response to the opacity of at least about 40% to 60%.

An aspect 22 according to of any one of aspects 14-21, wherein a saturation of the image is increased as a function of increasing the opacity of the at least partially transparent material of the substrate.

An aspect 23 according to aspect 22, wherein the saturation of the image is increased by increasing a total number of layers forming the at least one layer of the imaging material.

An aspect 24 according to aspect 22, wherein the saturation of the image is increased in substantially equal magnitudes as the increasing of the opacity of the at least partially transparent material of the substrate.

An aspect 25 according to any one of aspects 14-24, wherein the opacity of the at least partially transparent material of the substrate is established by at least one of hazing the substrate and texturing the substrate.

An aspect 26 according to any one of claims 14-25, wherein the substrate comprises one of glass material, glass ceramic material, strengthened glass material, strengthened glass-ceramic material and polymer material.

In an aspect 27, a consumer electronic product comprises: a housing comprising a front surface, a back surface and side surfaces; electrical components at least partially within the housing, the electrical components comprising at least a controller, a memory, and a display, the display at or adjacent the front surface of the housing; and a cover substrate disposed over the display, wherein at least one of a portion of the housing or the cover substrate comprises the apparatus of any one of aspects 14-26.

Although the disclosure herein has been described with reference to particular embodiments, it is to be understood that these embodiments are merely illustrative of the principles and applications of the embodiments herein. It is therefore to be understood that numerous modifications may be made to the illustrative embodiments and that other arrangements may be devised without departing from the spirit and scope of the present application.

1. A method, comprising:
applying at least one layer of an imaging material to form an image into direct or indirect contact with one of a first major surface and a second major surface of a substrate, where the second major surface is opposite the first major surface, and the substrate includes at least one edge surface extending between the first and second major surfaces,
wherein the substrate is formed from an at least partially transparent material comprising an opacity of 13.5% or more.

2. The method of claim 1, wherein the at least partially transparent material comprising an opacity of at least one of: 14.0%, 14.5%, 15.0%, 15.5%, and/or 16.0%

3. The method of claim 1, wherein one of:
the imaging material is applied directly onto the one of the first major surface and the second major surface of the substrate; and
the imaging material is applied onto a surface of a secondary substrate that is positioned relative to the one of the first major surface and the second major surface of the substrate.

4. The method of claim 1, further comprising applying at least one backing layer of a reflective material over the at least one layer of the imaging material, wherein:
the imaging material includes one or more inks;
the applying of the imaging material includes an ink printing technique;
the image exhibits a graininess, an appearance of which is substantially reduced by the opacity of the at least partially transparent material of the substrate as light reflects off of the backing layer, through the at least one layer of the imaging material, and through the substrate to a viewer; and
the graininess of the image is a function of a degree of variation in density of the ink of the imaging material within a given area.

5. The method of claim 4, wherein:
the substrate is formed from an at least partially transparent material comprising an opacity of between about 20% to 30%; and
the graininess of the image is reduced by about a factor of two in response to the opacity of at least about 20% to 30%.

6. The method of claim 4, wherein:
the substrate is formed from an at least partially transparent material comprising an opacity of between about 40% to 60%; and
the graininess of the image is reduced by about a factor of four in response to the opacity of at least about 40% to 60%.

7. The method of claim 1, further comprising at least one of:
increasing a saturation of the image as a function of increasing the opacity of the at least partially transparent material of the substrate;
increasing the saturation of the image by increasing a total number of layers forming the at least one layer of the imaging material; or
increasing the saturation of the image in substantially equal magnitudes as the increasing of the opacity of the at least partially transparent material of the substrate.

8. The method of claim 1, further comprising establishing the opacity of the at least partially transparent material of the substrate by at least one of hazing the substrate and texturing the substrate.

9. An apparatus, comprising:
a substrate comprising a first major surface, a second major surface opposite the first major surface, and at least one edge surface extending between the first and second major surfaces, where the first substrate is formed from an at least partially transparent material comprising an opacity of 13.5% or more; and
at least one layer of an imaging material in direct or indirect contact with one of the first major surface and the second major surface of the substrate to form an image.

10. The apparatus of claim 9, wherein the at least partially transparent material comprises an opacity of at least one of: 14.0%, 14.5%, 15.0%, 15.5%, and/or 16.0%.

11. The apparatus of claim 9, wherein one of:
the imaging material is in direct contact with the one of the first major surface and the second major surface of the substrate; and
the imaging material is on a surface of a secondary substrate that is positioned relative to the one of the first major surface and the second major surface of the substrate.

12. The apparatus of claim 9, further comprising at least one backing layer of a reflective material applied over the at least one layer of the imaging material, wherein:
the imaging material includes one or more inks;
the imaging material includes a printed ink;
the image exhibits a graininess, an appearance of which is substantially reduced by the opacity of the at least partially transparent material of the substrate as light reflects off of the backing layer, through the at least one layer of the imaging material, and through the substrate to a viewer; and
the graininess of the image is a function of a degree of variation in contrast of the ink of the imaging material within a given area.

13. The apparatus of claim 12, wherein:
the substrate is formed from an at least partially transparent material comprising an opacity of between about 20% to 30%; and
the graininess of the image is reduced by about a factor of two in response to the opacity of at least about 20% to 30%.

14. The apparatus of claim 12, wherein:
the substrate is formed from an at least partially transparent material comprising an opacity of between about 40% to 60%; and
the graininess of the image is reduced by about a factor of four in response to the opacity of at least about 40% to 60%.

15. The apparatus of claim 9, wherein the opacity of the at least partially transparent material of the substrate is due to at least one of the haze or the texture of the substrate.

16. A consumer electronic product, comprising:
a housing comprising a front surface, a back surface and side surfaces;
electrical components at least partially within the housing, the electrical components comprising at least a controller, a memory, and a display, the display at or adjacent the front surface of the housing; and
a cover substrate disposed over the display,
wherein at least one of a portion of the housing or the cover substrate comprises the apparatus of claim 9.
